(19) United States
(12) Patent Application Publication
(10) Pub. No.: US 2024/0105586 A1
(43) Pub. Date: Mar. 28, 2024

(54) INTEGRATED PASSIVE DEVICE WITH VIA FORMED IN ISOLATION TRENCH

(71) Applicant: Saras Mirco Devices, Inc., Chandler, AZ (US)

(72) Inventor: Courtney Timms, Atlanta, GA (US)

(21) Appl. No.: 18/472,188

(22) Filed: Sep. 21, 2023

Related U.S. Application Data
(60) Provisional application No. 63/376,688, filed on Sep. 22, 2022.

(51) Int. Cl. H01L 23/522; H01L 23/00; H01L 23/498

(52) U.S. Cl. CPC H01L 23/5223; H01L 23/49822; H01L 24/16; H01L 24/33; H01L 2224/16235; H01L 2224/16265; H01L 2224/3313; H01L 2224/33515; H01L 2924/1205; H01L 2924/19041

(57) ABSTRACT

An integrated passive device (IPD) comprises a conductive substrate having a front side and a back side and a plurality of layers including front and back dielectric layers and front and back conductive polymer layers, the plurality of layers defining front and back isolation trenches revealing the front and back sides of the substrate. The IPD may comprise a first metal contact electrically connected to the substrate by way of a blind via defined from a front outer surface of the IPD to the front side of the substrate and positioned within the front isolation trench. The IPD may comprise a second metal contact electrically isolated from the first and electrically connected to the polymer layers, connection to the back polymer layer being by way of a through via defined from the front surface to a back surface of the IPD and positioned within the front and back isolation trenches.

### CROSS-REFERENCE TO RELATED APPLICATIONS

This application relates to and claims the benefit of U.S. Provisional Application No. 63/376,688, filed Sep. 22, 2022 and entitled “VIA SLOTS IN ISOLATION TRENCH TO IMPROVE SERIES RESISTANCE, CAPACITANCE, AND ISOLATION AND METHODS OF MAKING THE SAME,” the entire contents of which is incorporated by reference herein.

### STATEMENT RE: FEDERALLY SPONSORED RESEARCH/DEVELOPMENT

Not Applicable

### BACKGROUND

The present disclosure generally relates to capacitors and, more particularly, to double-sided capacitors that exhibit high capacitance and low series resistance.

Capacitors are an important part of many integrated and embedded circuits and are commonly used as energy storage structures, filters, or as specific components of complex circuits. Capacitors generally make use of high surface area to achieve high capacitance values and are commonly arranged as a pair of thin electrodes separated by a dielectric and rolled into a tight cylindrical structure to optimize the surface area per unit volume. They are also made as deep trenches in silicon to benefit from more surface area, or as layers of dielectric and metal stacked and connected to each other to benefit from both permittivity and surface area.

Efforts to maximize capacitance and minimize equivalent series resistance (ESR) of capacitors have led to the development of double-sided capacitors such as those described in Applicant's own U.S. Patent Application Pub. No. 2023/0067888, entitled “Planar High-Density Aluminum Capacitors for Stacking and Embedding” (“the '888 publication”), and U.S. patent application Ser. No. 18/223,194 (“the '194 application”), filed Jul. 18, 2023 and entitled “Pre-Drilled Vias to capture Double Sided Capacitance,” the entire contents of each of which is incorporated by reference herein. Such arrangements may define a second electrode (e.g., a cathode), such as a conductive polymer, metal, or ceramic, that is disposed on both sides of a first electrode (e.g., an anode) made of aluminum that has been etched or otherwise modified to have a high surface area, with an oxide layer formed therebetween to act as the dielectric. While such double-sided capacitors have the potential to double the usable surface area of the first electrode, they require the formation of structures for accessing the first and second electrodes, including the side of the first electrode that is opposite to the device terminals. To this end, blind and through vias may be formed and filled with a conductive material to provide electrical connections between the electrodes and the device terminals. However, these vias take up valuable surface area, limiting the capacitance of the device. At the same time, when such vias are cut through the built-up stack, their formation may generate heat (due to laser drilling, for example), which may lower the conductivity of the second electrode material, increasing the ESR of the capacitor. In the worst case, debris and mechanical tensions caused by via formation may lead to delamination or fracture, resulting in device failure.

### BRIEF SUMMARY

The present disclosure contemplates various devices and methods for overcoming the above drawbacks accompanying the related art. One aspect of the embodiments of the present disclosure is an integrated passive device (IPD) comprising a conductive substrate having a front side and a back side and a plurality of layers including a front dielectric layer on the front side of the conductive substrate, a back dielectric layer on the back side of the conductive substrate, a front conductive polymer layer on the front dielectric layer, and a back conductive polymer layer on the back dielectric layer. The plurality of layers may define a front isolation trench revealing the front side of the conductive substrate and a back isolation trench revealing the back side of the conductive substrate. The IPD may further comprise a first metal contact electrically connected to the conductive substrate by way of a first blind via defined from a front outer surface of the IPD to the front side of the conductive substrate. The first blind via may be positioned within the front isolation trench. The IPD may further comprise a second metal contact electrically isolated from the first metal contact and electrically connected to the front and back conductive polymer layers. The second metal contact may be electrically connected to the back conductive polymer layer by way of a through via defined from the front outer surface of the IPD to a back outer surface of the IPD. The through via may be positioned within the front isolation trench and the back isolation trench.

The front isolation trench may include a first stretch and a second stretch on opposite borders of the IPD. The first blind via may be positioned within the first stretch of the front isolation trench. The through via may be positioned within the second stretch of the front isolation trench. The front isolation trench may include a third stretch and a fourth stretch on opposite borders of the IPD connecting the first and second stretches of the front isolation trench.

The IPD may comprise a third metal contact electrically connected to the conductive substrate by way of a second blind via defined from a back outer surface of the IPD to the back side of the conductive substrate. The second blind via may be positioned within the back isolation trench. The back isolation trench may include a first stretch and a second stretch on opposite borders of the IPD respectively aligned with the first and second stretches of the front isolation trench. The second blind via may be positioned within the first stretch of the back isolation trench. The through via may be positioned within the second stretch of the back isolation trench. The back isolation trench may include a third stretch and a fourth stretch on opposite borders of the IPD connecting the first and second stretches of the back isolation trench.

Another aspect of the embodiments of the present disclosure is an IPD comprising a conductive substrate having a front side and a back side and a plurality of layers including a front dielectric layer on the front side of the conductive substrate, a back dielectric layer on the back side of the conductive substrate, a front conductive polymer layer on the front dielectric layer, and a back conductive polymer layer on the back dielectric layer. The plurality of layers may define a front isolation trench revealing the front side of the conductive substrate and a back isolation trench revealing the back side of the conductive substrate. The IPD may further comprise a first metal contact electrically connected to the conductive substrate and a second metal contact electrically isolated from the first metal contact and electrically connected to the front and back conductive polymer layers. The second metal contact may be electrically connected to the back conductive polymer layer by way of a through via defined from the front outer surface of the IPD to a back outer surface of the IPD. The through via may be positioned within the front isolation trench and the back isolation trench.

The front isolation trench may include a first stretch and a second stretch on opposite borders of the IPD. The back isolation trench may include a first stretch and a second stretch on opposite borders of the IPD respectively aligned with the first and second stretches of the front isolation trench. The through via may be positioned within the second stretch of the front isolation trench and the second stretch of the back isolation trench. The front isolation trench may include a third stretch and a fourth stretch on opposite borders of the IPD connecting the first and second stretches of the front isolation trench. The back isolation trench may include a third stretch and a fourth stretch on opposite borders of the IPD connecting the first and second stretches of the back isolation trench.

Another aspect of the embodiments of the present disclosure is an IPD comprising a conductive substrate having a front side and a back side and a plurality of layers including a front dielectric layer on the front side of the conductive substrate, a back dielectric layer on the back side of the conductive substrate, a front conductive polymer layer on the front dielectric layer, and a back conductive polymer layer on the back dielectric layer. The plurality of layers may define a front isolation trench revealing the front side of the conductive substrate and a back isolation trench revealing the back side of the conductive substrate. The IPD may further comprise a first metal contact electrically connected to the conductive substrate by way of a first blind via defined from a front outer surface of the IPD to the front side of the conductive substrate. The first blind via may be positioned within the front isolation trench. The IPD may further comprise a second metal contact electrically isolated from the first metal contact and electrically connected to the front and back conductive polymer layers.

The front isolation trench may include a first stretch and a second stretch on opposite borders of the IPD. The first blind via may be positioned within the first stretch of the front isolation trench. The IPD may comprise a third metal contact electrically connected to the conductive substrate by way of a second blind via defined from a back outer surface of the IPD to the back side of the conductive substrate, the second blind via being positioned within the back isolation trench. The back isolation trench may include a first stretch and a second stretch on opposite borders of the IPD respectively aligned with the first and second stretches of the front isolation trench. The second blind via may be positioned within the first stretch of the back isolation trench. The front isolation trench may include a third stretch and a fourth stretch on opposite borders of the IPD connecting the first and second stretches of the front isolation trench. The back isolation trench may include a third stretch and a fourth stretch on opposite borders of the IPD connecting the first and second stretches of the back isolation trench.

In the IPD of any of the aspects of the embodiments of the present disclosure, the plurality of layers may include a front metallization layer arranged to promote electrical conductivity between the front conductive polymer layer and the second metal contact and a back metallization layer arranged to promote electrical conductivity between the back conductive polymer layer and the second metal contact. The plurality of layers may include a front carbonaceous layer on the front conductive polymer layer and a back carbonaceous layer on the back conductive polymer layer. The front metallization layer may be on the front carbonaceous layer and the back metallization layer being on the back carbonaceous layer.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a perspective view of an integrated passive device (IPD) according to an embodiment of the present disclosure;

FIG. 2 is another perspective view of the IPD with the top metal contacts shown in phantom;

FIG. 3 is a cross-sectional view of the IPD;

FIG. 3A is a close-up view of the region marked “3A” in FIG. 3;

FIG. 4 is a schematic top view of the IPD;

FIG. 5 is an exemplary graphical representation comparing series resistance of capacitors having a structure according to the disclosed embodiments with series resistance of capacitors having a different structure;

FIG. 6 is another exemplary graphical representation comparing series resistance of capacitors having a structure according to the disclosed embodiments with series resistance of capacitors having a different structure;

FIG. 7 is an exemplary graphical representation comparing capacitance of capacitors having a structure according to the disclosed embodiments with capacitance of capacitors having a different structure;

FIG. 8 is another exemplary graphical representation comparing series resistance of capacitors having a structure according to the disclosed embodiments with series resistance of capacitors having a different structure;

FIG. 9 is another exemplary graphical representation comparing capacitance of capacitors having a structure according to the disclosed embodiments with capacitance of capacitors having a different structure;

FIG. 10 is an exemplary graphical representation comparing a series resistance distribution for capacitors having a structure according to the disclosed embodiments with a series resistance distribution for other capacitors having a different structure;

FIG. 11 is a schematic top view of another IPD according to an embodiment of the present disclosure;

FIG. 12 is a schematic top view of another IPD according to an embodiment of the present disclosure;

FIG. 13 is a schematic top view of another IPD according to an embodiment of the present disclosure; and

FIG. 14 is a schematic top view of another IPD according to an embodiment of the present disclosure.

### DETAILED DESCRIPTION

The present disclosure encompasses various embodiments of integrated passive devices (IPD) containing capacitors and methods of manufacturing the same. The detailed description set forth below in connection with the appended drawings is intended as a description of several currently contemplated embodiments and is not intended to represent the only form in which the disclosed subject matter may be developed or utilized. The description sets forth the functions and features in connection with the illustrated embodiments. It is to be understood, however, that the same or equivalent functions may be accomplished by different embodiments that are also intended to be encompassed within the scope of the present disclosure. It is further understood that the use of relational terms such as first and second and the like are used solely to distinguish one from another entity without necessarily requiring or implying any actual such relationship or order between such entities.

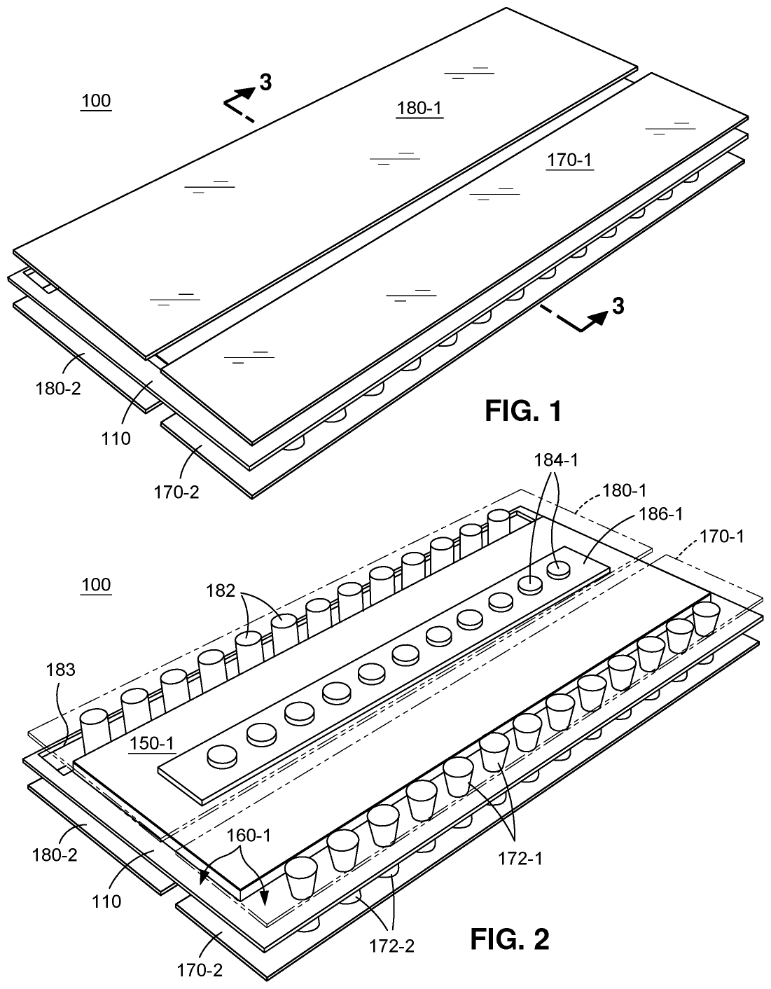

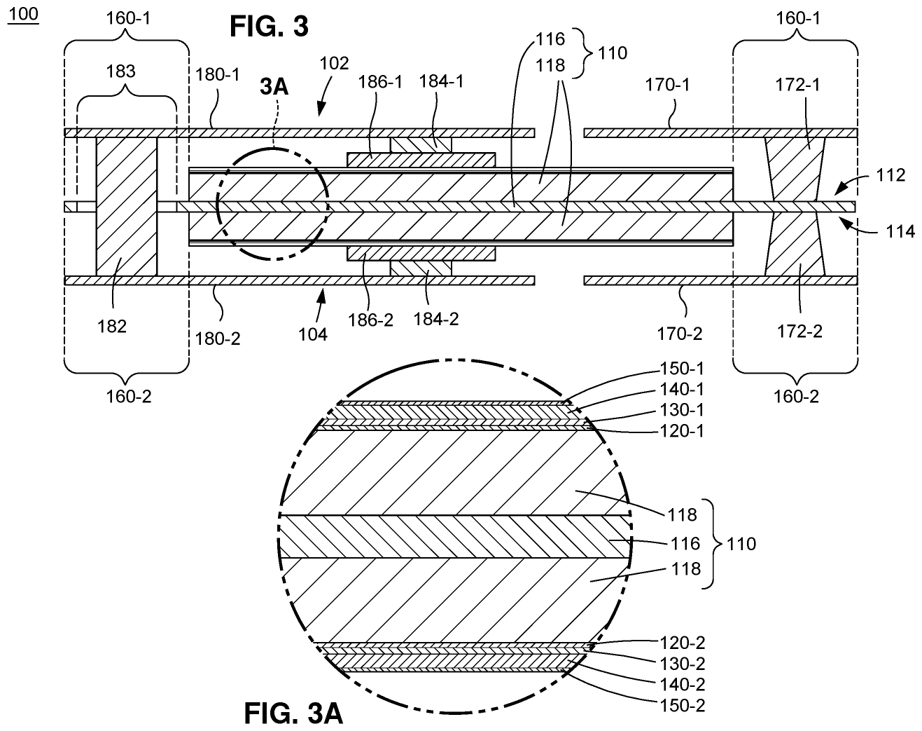

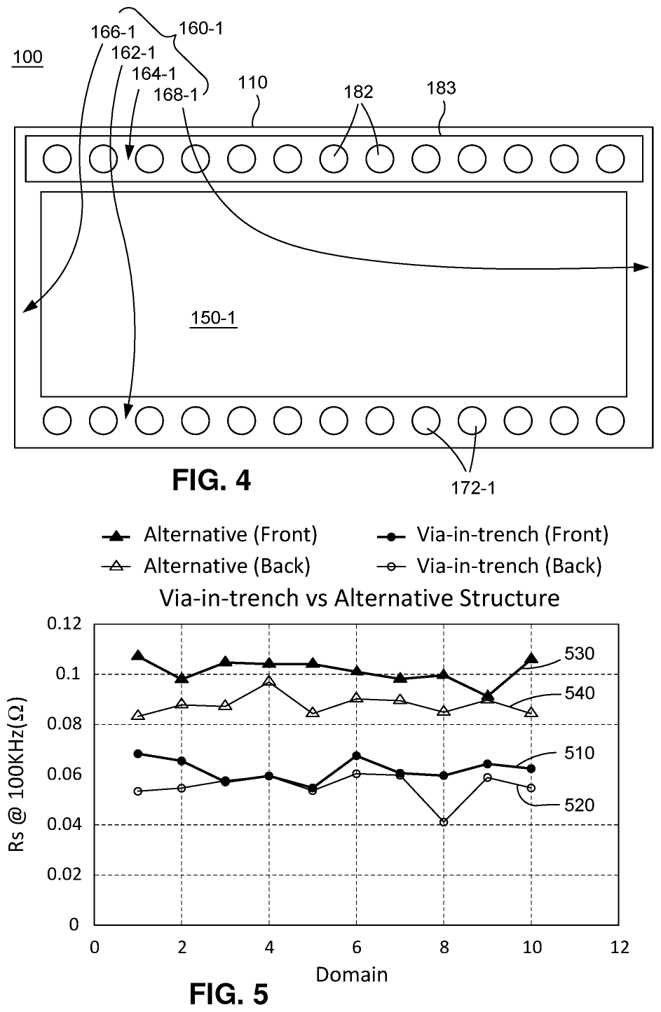

FIGS. 1 and 2 are perspective views of an IPD 100 according to an embodiment of the present disclosure, with FIG. 2 being the same as FIG. 1 except that the top metal contacts 170-1, 180-1 are shown in phantom so that the interior layers can be more easily seen. FIG. 3 is a cross-sectional view taken along the line 3-3 in FIG. 1 (with FIG. 3A being a closeup view thereof), and FIG. 4 is a schematic top view of the IPD 100. The IPD 100, which contains a single double-sided capacitor in this example, may comprise a conductive substrate 110 serving as a first electrode (e.g., an anode), a dielectric layer 120-1, 120-2, and a conductive polymer layer 130-1, 130-2 serving as a second electrode (e.g., a cathode). In order to achieve effectively twice the surface area and thus twice the capacitance of a single-sided device, the capacitor may be double-sided in the sense that the dielectric layer 120-1, 120-2 may include a front dielectric layer 120-1 provided on a front side 112 of the conductive substrate 110 as well as a back dielectric layer 120-2 provided on a back side 114 of the conductive substrate 110, with the conductive polymer layer 130-1, 130-2 including a front conductive polymer layer 130-1 on the front dielectric layer 120-1 and a back conductive polymer layer 130-2 on the back dielectric layer 120-2. The IPD 100 may be isolated from other devices formed on the same conductive substrate 110 by isolation trenches 160-1, 160-2 that demarcate the boundaries of the second electrode (e.g., cathode). In the illustrated example, which may be especially suitable for reverse bias applications, the isolation trenches 160-1, 160-2 may go only as deep as the conductive substrate 110 serving as the first electrode (e.g., anode), with the same first electrode thus being shared by multiple capacitors that are separated by the isolation trenches 160-1, 160-2. In this regard, the plurality of layers 120-1, 120-2, 130-1, 130-2 may define a front isolation trench 160-1 revealing the front side 112 of the conductive substrate 110 (e.g., cut through the front layers 120-1, 130-1) and a back isolation trench 160-1 revealing the back side 114 of the conductive substrate 110 (e.g., cut through the back layers 120-2, 130-2). However, it is contemplated that isolation may also entail cutting through the conductive substrate 110 itself, for example, as described in the '194 application, which may improve the suitability of the IPD 100 for forward bias applications.

Advantageously, one or both of these same isolation trenches 160-1, 160-2 may be the site of features such as vias for connecting the IPD 100 to external devices in order to incorporate the IPD 100 into energy storage structures, filters, or other circuit components depending on the particular application. In this way, the same area of the substrate 110 that is reserved for isolation may be leveraged to make electrical connections to the device terminals, allowing for a more efficient use of surface area that reduces the risk of thermal and mechanical damage by eliminating the need to drill through other portions of the layer buildup. In particular, the terminals of the IPD 100 may include a first metal contact 170-1 (e.g., an anode terminal) that is electrically connected to the conductive substrate 110 by way of one or more first blind vias 172-1 defined from a front outer surface 102 of the IPD 100 to the front side 112 of the conductive substrate 110. As shown, the first blind via(s) 172-1 may advantageously be positioned within the front isolation trench 160-1. The terminals of the IPD 100 may further include a second metal contact 180-1 (e.g., a cathode terminal) that is electrically isolated from the first metal contact 170-1 and electrically connected to the front and back conductive polymer layers 130-1, 130-2. The second metal contact 180-1 may be connected to the front conductive polymer layer 130-1 by way of one or more blind vias 184-1 formed between the second metal contact 180-1 and a landing pad 186-1 that is electrically connected to the front conductive polymer layer 130-1 (e.g., with intervening carbon and metal layers as described below). The second metal contact 180-1 may also be electrically connected to the back conductive polymer layer 130-2 by way of one or more through vias 182 defined from the front outer surface 102 of the IPD 100 to a back outer surface 104 of the IPD 100. For example, the through via(s) 182 may terminate at another metal contact 180-2 formed on the back outer surface 104 of the IPD 100, which may be connected to the back conductive polymer layer 130-2 by way of one or more blind vias 184-2 formed between the second metal contact 180-2 and a landing pad 186-2 that is electrically connected to the back conductive polymer layer 130-2 (e.g., with intervening carbon and metal layers as described below). As shown, the through via(s) 182 may advantageously be positioned within the front isolation trench 160-1 and the back isolation trench 160-2.

In addition to the first and second metal contacts 170-1, 180-1, which may be provided on the front outer surface 102 of the IPD 100 (allowing for connection of the IPD 100 to external circuits from a single side in some cases), the IPD 100 may additionally have third and/or fourth metal contacts 170-2, 180-2 provided on the back outer surface 104 of the IPD 100 opposite the front outer surface 102. The third metal contact 170-2 may be electrically connected to the conductive substrate 110 by way of one or more second blind vias 172-2 defined from the back outer surface 104 of the IPD 100 to the back side 114 of the conductive substrate 110. As shown, the second blind via(s) 172-2 may be positioned within the back isolation trench 160-2. The fourth metal contact 180-2 may, as described above, be electrically connected to the second metal contact 180-1 and to the front and back conductive polymer layers 130-1, 130-2 by way of the through via(s) 182, the blind vias 184-1, 184-2, and the landing pads 186-1, 186-2. In the case of multiple stacked capacitors within the same IPD 100, it is contemplated that the passthrough connection defined by the through via 182 and the second and fourth metal contacts 180-1, 180-2 may be preserved through stacking (i.e., may remain unblocked and functional) by the implementation of appropriate stacking arrangements.

As best seen in FIG. 4, the front isolation trench 160-1 may include a first stretch 162-1 and a second stretch 164-1 on opposite borders of the IPD 100, as well as (e.g., in the case of a rectangular IPD 100) a third stretch 166-1 and a fourth stretch 168-1 on opposite borders of the IPD 100 connecting the first and second stretches 162-1, 164-2. While not separately illustrated, the back isolation trench 160-2 may likewise include first, second, third, and fourth stretches 162-2, 164-2, 166-2, 168-2 that are respectively aligned with the first, second, third, and fourth stretches 162-1, 164-1, 166-1, 168-1 of the front isolation trench 160-1. The one or more first blind vias 172-1 may be positioned within the first stretch 162-1 of the front isolation trench 160-1, and the one or more second blind vias 172-2 (not visible in FIG. 4) may be positioned within the first stretch 162-2 of the back isolation trench 160-2. For example, the isolation trenches 160-1, 160-2 may be formed by laser processing and filled with an insulating material such as an Ajinomoto Build-up Film (ABF) or other thermosetting film, after which the insulating material may be drilled and filled with a conductive via fill at one or more positions to form the individual first and second blind via(s) 172-1, 172-2. On the opposite border of the IPD 100, the one or more through vias 182 may be positioned within the second stretch 164-1 of the front isolation trench 160-1 and the second stretch 164-2 of the back isolation trench 160-2. In the case of the through vias 182, a through via region 183 may first be defined within the second stretches 164-1, 164-2 by laser processing all the way through the conductive substrate 110 (in some cases by pre-drilling as described in the '194 application) prior to filling with the ABF or other insulating material. The insulating material may then be drilled and filled with a conductive via fill at one or more positions within the through via region 183 to form the individual through via(s) 182.

A process of making the IPD 100 may begin with providing the conductive substrate 110, which may be made of aluminum, an aluminum alloy, or another material that is etched or otherwise modified to have a high surface area, such as an etched aluminum foil as described in the '888 publication. Alternative or additional modifications to increase the surface area of the conductive substrate 110 may include deposition of a sintered aluminum powder or other aluminum, aluminum oxide, titanium, or titanium oxide powder thereon. The conductive substrate 110 may be a metal foil as described in Applicant's own U.S. Patent Application Pub. No. 2023/0073898, entitled “Modified Metal Foil Capacitors and Methods for Making Same,” the entire contents of which is incorporated by reference herein. As illustrated, the conductive substrate 110 may thus comprise a solid metal portion 116 and a high surface area portion 118 on front and back sides 112, 114 thereof. It is noted that the formation of isolation trenches 160-1, 160-2 and blind vias 172-1, 172-2 from the outside of the IPD 100 to the front or back side 112, 114 of the conductive substrate 110 may (though need not necessarily) stop at the solid metal portion 116 as illustrated in FIG. 3.

The dielectric layer 120-1, 120-2 (separately referenced as front and back layers), which may be a naturally occurring oxide layer (e.g., an aluminum oxide layer) or one that has been grown by an anodization process (e.g., by placing the conductive substrate 110 in an electrolytic solution and passing a current through the solution), grown by thermal oxidation in a humidity chamber, or coated on the conductive substrate 110 (e.g., by atomic layer deposition), may then be formed on both sides of the conductive substrate 110. As may be appreciated, the dielectric layer 120-1, 120-2 may, in general, exhibit the same high surface area as the underlying conductive substrate 110 as it fills in and takes the shape of the various tunnels and recesses that may result from the etching or other modification to the material of the conductive substrate 110. Higher dielectric constant materials are also contemplated in order to improve capacitance for the same surface area, such as HfO₂, ZrO₂, BaO, and TiO₂. These materials may be deposited instead of or in addition to aluminum oxide (Al₂O₃), for example, by conformal deposition such as selective atomic layer deposition (ALD).

The conductive polymer layer 130-1, 130-2 may then be provided on the front and back dielectric layers 120-1, 120-2, in some cases following a process of pre-drilling one or more vias as described in the '194 application. In this way, the second electrode (e.g., cathode) defined by the conductive polymer layer 130-1, 130-2 may beneficially extend over both sides of the first electrode (e.g., anode) defined by the conductive substrate 110 with the dielectric layer 120-1, 120-2 therebetween, effectively taking advantage of both sides of the conductive substrate 110 to double the surface area and thus the capacitance. It is noted that, like the dielectric layer 120-1, 120-2, the conductive polymer layer 130-1, 130-2 may exhibit the same high surface area as the underlying conductive substrate 110 as it fills in and takes the shape of the various tunnels and recesses that may result from the etching or other modification to the material of the conductive substrate 110, in this case with the dielectric layer 120-1, 120-2 sandwiched therebetween. A variety of conductive polymers may be suitable for use as the second electrode of the capacitor described herein. The conductive polymer layer 130-1, 130-2 may, for example, comprise one or more of a polypyrrole, a polythiophene, a polyaniline, a polyacetylene, a polyphenylene, a poly(p-phenylene-vinylene), PEDOT:PSS (poly(3,4-ethylenedioxythiophene) polystyrene sulfonate), or P3HT (poly(3-hexylthiophene-2,5-diyl)).

As shown in FIGS. 3 and 3A, additional layers may be built up on the conductive polymer layer 130-1, 130-2 in order to improve the electrical connection between the polymer layer 130-1, 130-2 and the second metal contact 180-1 (as well as the fourth metal contact 180-2 if included). For example, a carbonaceous layer 140-1, 140-2 (individually referenced as front and back layers) and/or a metallization layer 150-1, 150-2 (individually referenced as front and back layers) may be applied on the conductive polymer layer 130-1, 130-2. The front and back carbonaceous layers 140-1, 140-2 may be applied in direct, physical contact with the front and back conductive polymer layers 130-1, 130-2, respectively, and the front and back metallization layers 150-1, 150-2 may be applied on the conductive polymer layer 130-1, 130-2 by being in direct, physical contact with the respective carbonaceous layers 140-1, 140-2 thereon. Preferably, the application of the metallization layer 150-1, 150-2 may comprise depositing a diffusion barrier on the conductive polymer layer (e.g., directly in contact with the carbonaceous layer 140-1, 140-2 thereon) and depositing metal adjacent the diffusion barrier. The carbonaceous layer 140-1, 140-2, if included, may advantageously reduce a contact resistance between the conductive polymer layer 130-1, 130-2 and other components, such as a diffusion barrier layer of the metallization layer 150-1, 150-2. The carbonaceous layer 140-1, 140-2 may include, for example, carbon black, graphite, a carbon-based ink, or a polymeric, and may be applied using a variety of techniques, such as screen printing, inkjet printing, sputter deposition, vacuum deposition, spin coating, doctor blading, or the like. The metallization layer 150-1, 150-2 may be used to provide high-quality electrical conductivity between the respective conductive polymer layer 130-1, 130-2 (acting as the second electrode of the capacitor) and the second and fourth metal contacts 180-1, 180-2 for electrical connection of the IPD 100 with an external circuit. The metallization layer 150-1, 150-2 may include a metal such as Ag, Au, Cu, Pt, Pd, and/or composites or alloys of the aforementioned metals, or in some cases polymers such as epoxies, silicones, or fluoroelastomers. Including a diffusion barrier layer in the metallization layer 150-1, 150-2 may limit infiltration of components from the metallization layer 150-1, 150-2 into the carbonaceous layer 140-1, 140-2 or conductive polymer layer 130-1, 130-2. Example materials for a diffusion barrier layer include, but are not limited to, Ti, W, Cr, Ti—W, TaN, and/or Co—W. The metallization layer 150-1, 150-2, as well as any diffusion barrier layer thereof, may be applied using any suitable techniques, such as vacuum deposition (e.g., sputter deposition).

After the stack buildup on both sides of the conductive substrate 110, the isolation trenches 160-1, 160-2 may be formed, followed by formation of the blind and through vias 172-1, 172-2, 182 within the isolation trenches 160-1, 160-2 as described above. Additional vias 184-1, 184-2 and landing pads 186-1, 186-2 may be formed at this stage as well for electrical connection of the second and fourth metal contacts 180-1, 180-2 to the conductive polymer layers 130-1, 130-2 serving as the second electrode of the capacitor. It is noted that the ABF or other insulating material into which the vias 172-1, 172-2, 182, 184-1, 184-2 are drilled (prior to being filled with a conductive via fill) may remain and may serve to fill in all the remaining space of the IPD 100 to prevent shorting of the electrodes (though for ease of illustration the insulating material is not shown). The metal contacts 170-1, 170-2, 180-1, 180-2 may then be formed on the outermost surfaces 102, 104 of the IPD 100 (e.g., on the insulating material) in contact with the vias 172-1, 172-2, 182, 184-1, 184-2, thus establishing the electrical connections described above. In this way, the resulting IPD 100 may advantageously utilize the area of the existing isolation trenches 160-1, 160-2 for connection of the capacitor to external devices, thus avoiding any additional removal of the layer buildup representing the domain area of the capacitor.

FIG. 5 is an exemplary graphical representation comparing series resistance Rs of capacitors having a structure according to the disclosed embodiments with series resistance Rs of capacitors having a different structure. In particular, plots 510 and 520 show series resistance Rs as measured for different capacitors (labeled as domains 1 through 10) formed on a shared substrate as described herein, namely, having blind and through vias formed within the isolation trenches (i.e., via-in-trench structure), with plot 510 representing resistance measurements taken from the front side of the substrate and plot 520 representing resistance measurements taken from the back side of the substrate. Plots 530 and 540 show corresponding front and back side resistance measurements for capacitors having an alternative structure in which the blind and through vias are formed outside of the isolation trenches. As shown, the capacitors having the disclosed via-in-trench structure achieve lower series resistance Rs.

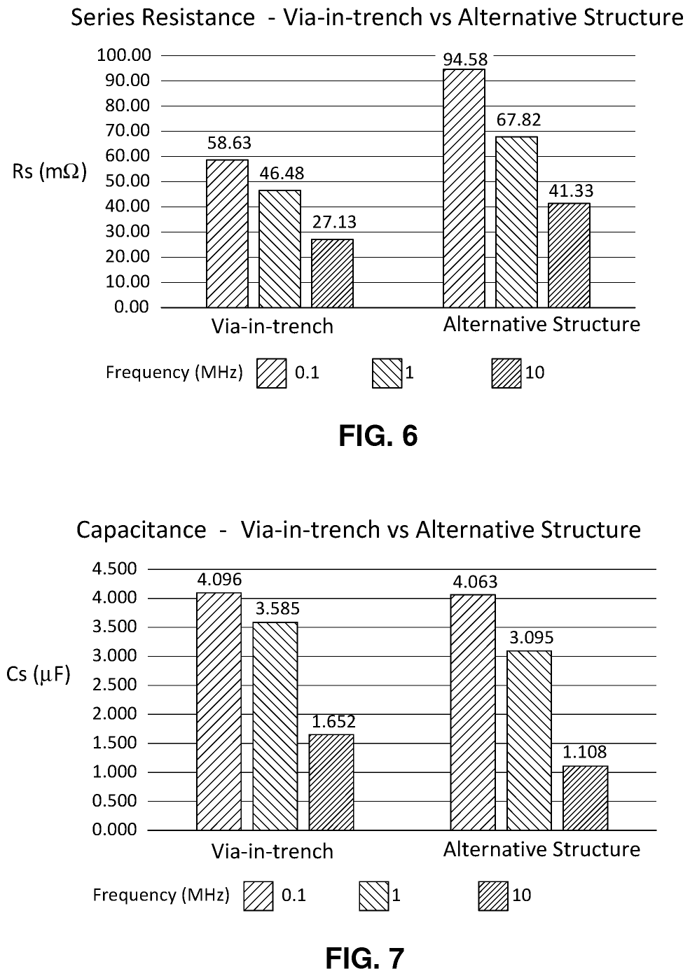

FIG. 6 is another exemplary graphical representation comparing series resistance Rs of capacitors having a structure according to the disclosed embodiments with series resistance Rs of capacitors having a different structure. FIG. 7 similarly compares capacitance Cs. As can be seen, the capacitors having the disclosed via-in-trench structure achieve lower series resistance Rs both at 0.1 MHz (100 KHz) and at higher frequencies 1 MHz and 10 MHz. For example, series resistance Rs at 0.1 MHz is 38% less for the via-in-trench than the alternative structure. In addition, series resistance Rs at 1 MHz is 31% less using the via-in-trench structure, and series resistance Rs at 10 MHz is 34% less using the via-in-trench structure. Meanwhile, capacitance at 100 kHz is similar for both structures, but less droop is observed at higher frequencies for the disclosed via-in-trench structure.

Exemplary capacitor cells are shown in Tables 1 and 2, below, with Table 1 showing layout measurements for three types of cells A, B, and C for the via-in-trench design and Table 2 showing layout measurements for three corresponding types of cells A, B, and C for an alternative design in which the blind and through vias are formed outside of the isolation trenches:

TABLE 1

| | A Cell | | | B Cell | | | C Cell | | |
|---|---|---|---|---|---|---|---|---|---|
| | XDIM | YDIM | AREA | XDIM | YDIM | AREA | XDIM | YDIM | AREA |
| | (mm) | (mm) | (mm2) | (mm) | (mm) | (mm2) | (mm) | (mm) | (mm2) |
| Domain | 2 | 1.6 | 3.2 | 4 | 1.6 | 6.4 | 13 | 1.5625 | 20.3125 |
| BS | 2.2 | 0.3 | 0.66 | 4.2 | 0.3 | 1.26 | 13.2 | 0.6 | 7.92 |
| TSBS | 2.2 | 0.3 | 0.66 | 4.2 | 0.3 | 1.26 | 13.2 | 0.6 | 7.92 |
| TS | 2.15 | 0.25 | 0.5375 | 4.15 | 0.25 | 10.375 | 13.15 | 0.5 | 6.575 |

| | | | | | |
|---|---|---|---|---|---|
| Effective Area: | 3.2 | Effective Area: | 6.4 | Effective Area: | 20.3125 |

TABLE 2

| | A Cell | | | B Cell | | | C Cell | | |
|---|---|---|---|---|---|---|---|---|---|
| | XDIM | YDIM | AREA | XDIM | YDIM | AREA | XDIM | YDIM | AREA |
| | (mm) | (mm) | (mm²) | (mm) | (mm) | (mm²) | (mm) | (mm) | (mm²) |
| Domain | 2 | 2 | 4 | 4 | 2 | 8 | 13 | 2.5125 | 32.6625 |
| BS | 1.575 | 0.3 | 0.4725 | 3.375 | 0.3 | 1.0125 | 12.375 | 0.565 | 6.991875 |
| TSBS | 1.595 | 0.32 | 0.5104 | 3.395 | 0.32 | 1.0864 | 12.375 | 0.565 | 6.991875 |
| TS | 1.475 | 0.2 | 0.295 | 3.275 | 0.2 | 0.655 | 12.28 | 0.47 | 5.7716 |

| | | | | | |
|---|---|---|---|---|---|
| Effective Area: | 3.0171 | Effective Area: | 5.9011 | Effective Area: | 18.67875 |

In Tables 1 and 2, “BS” stands for “blind slot” and refers to the dimensions of the area containing the blind vias 172-1, 172-2, “TS” stands for “through slot” and refers to the dimensions of the through via region 183 containing the through vias 182, and “TSBS” refers to “through slot blind slot” and refers to a blind feature cut prior to the through via region 183 to ensure the stack is not shorted when creating the through via region 183. The effective area of each cell is the original domain area (e.g., 4 mm² in the case of the A cell) minus the BS area and the TSBS area (without additionally subtracting the TS area because it is defined within the TSBS area). The effective area refers to that area of a single side of the capacitor (and would effectively be doubled for double-sided capacitors as described herein. As can be seen, the via-in-trench structure of Table 1 supports an 82% increase in TS size for A cells, a 58% increase in TS size for B cells, and a 13% increase in TS size for C cells relative to the alternative structure, resulting in effective area increases of 6%, 8.4%, and 8.7%, respectively. In this example, the A, B, and C cells of Table 1 have the same footprint as the A, B, and C cells of Table 2: 2.2 mm by 2.2 mm for an A cell, 2.2 mm by 4.2 mm for a B cell, and 2.7125 by 13.2 mm for a C cell.

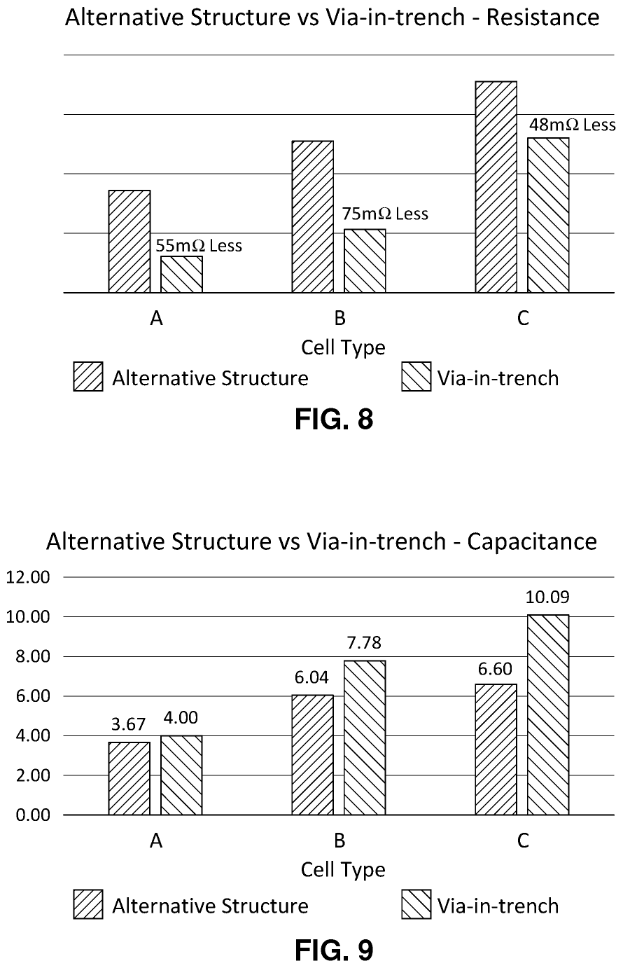

FIG. 8 is another exemplary graphical representation comparing series resistance Rs of capacitors having a structure according to the disclosed embodiments with series resistance Rs of capacitors having a different structure. As can be seen, resistance at 100 kHz is 64% less for A cells made using the via-in-trench structure (Table 1) as compared to A cells made using the alternative structure (Table 2). FIG. 9 similarly compares capacitance Cs. Scaling of capacitance with area is closer to expected behavior for the via-in-trench structure.

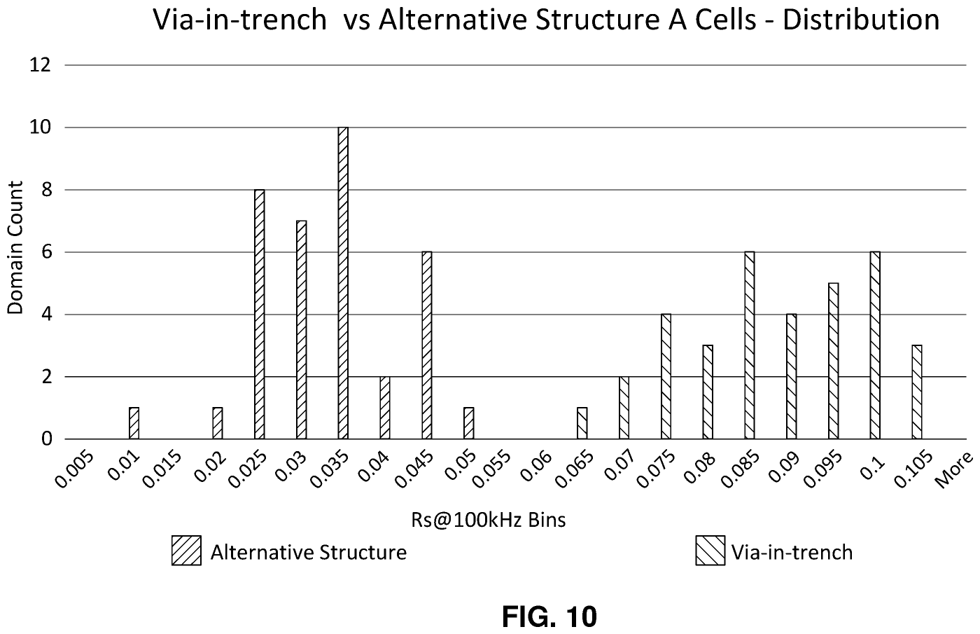

FIG. 10 is an exemplary graphical representation comparing a series resistance distribution for capacitors having a structure according to the disclosed embodiments with a series resistance distribution for other capacitors having a different structure. As can be seen, there are large differences in series resistance Rs distribution measurements (in milliohms) between the via-in-trench and the alternative structure. Both data sets follow normal distributions, but the via-in-trench data is shifted to the left by about 50 milliohms.

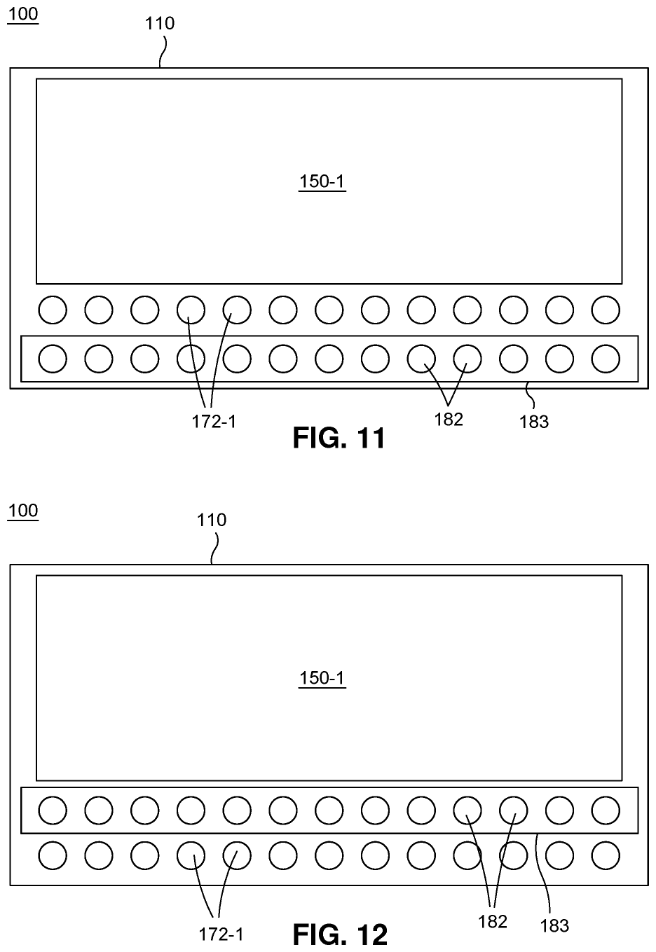

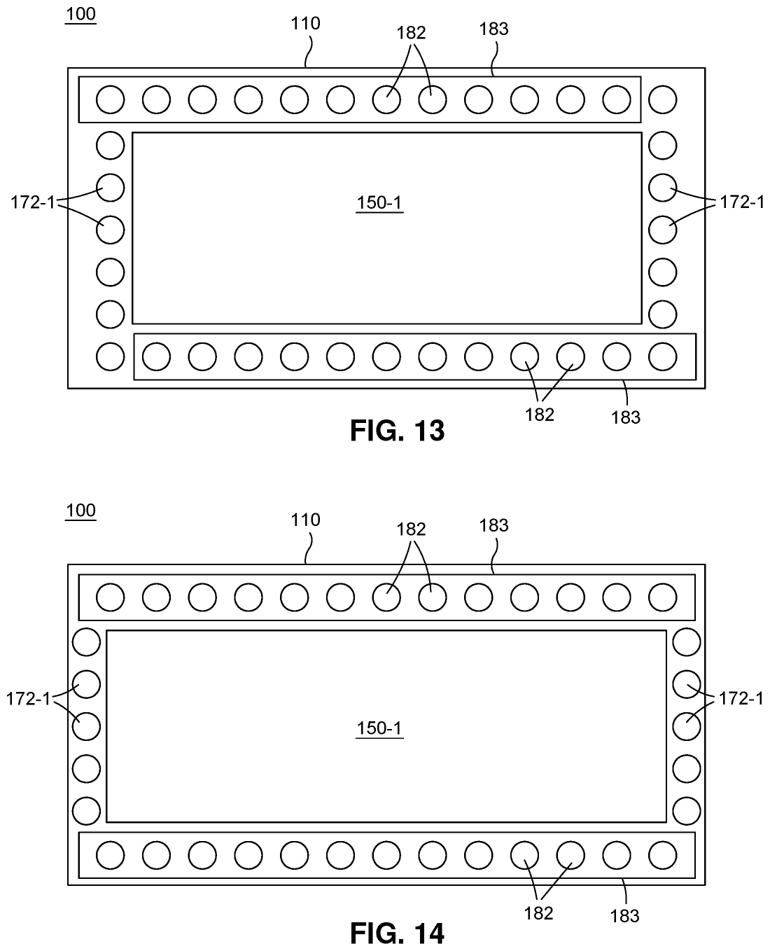

FIGS. 11-14 are schematic top views showing modified layouts of the IPD 100. The layouts of FIGS. 11 and 12, in which the blind vias 172-1 (and 172-2) and the through vias 182 are within the same stretch of the isolation trench, may advantageously improve via inductance. FIGS. 13 and 14 are example layouts that accommodate multiple regions for the blind vias 172-1 (and 172-2) and the through vias 182 by utilizing additional stretches of the isolation trench. In the case of a square IPD 100 (as opposed to the illustrated elongated rectangle), the layout of FIG. 13 may allow for via regions having uniform area around the border of the IPD 100.

The above description is given by way of example, and not limitation. Given the above disclosure, one skilled in the art could devise variations that are within the scope and spirit of the invention disclosed herein. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. An integrated passive device (IPD) comprising:
a conductive substrate having a front side and a back side;
a plurality of layers including a front dielectric layer on the front side of the conductive substrate, a back dielectric layer on the back side of the conductive substrate, a front conductive polymer layer on the front dielectric layer, and a back conductive polymer layer on the back dielectric layer, the plurality of layers defining a front isolation trench revealing the front side of the conductive substrate and a back isolation trench revealing the back side of the conductive substrate;
a first metal contact electrically connected to the conductive substrate by way of a first blind via defined from a front outer surface of the IPD to the front side of the conductive substrate, the first blind via being positioned within the front isolation trench; and
a second metal contact electrically isolated from the first metal contact and electrically connected to the front and back conductive polymer layers, the second metal contact being electrically connected to the back conductive polymer layer by way of a through via defined from the front outer surface of the IPD to a back outer surface of the IPD, the through via being positioned within the front isolation trench and the back isolation trench.

2. The integrated passive device of claim 1, wherein the front isolation trench includes a first stretch and a second stretch on opposite borders of the IPD, the first blind via being positioned within the first stretch of the front isolation trench and the through via being positioned within the second stretch of the front isolation trench.

3. The integrated passive device of claim 2, wherein the front isolation trench includes a third stretch and a fourth stretch on opposite borders of the IPD connecting the first and second stretches of the front isolation trench.

4. The integrated passive device of claim 1, further comprising a third metal contact electrically connected to the conductive substrate by way of a second blind via defined from a back outer surface of the IPD to the back side of the conductive substrate, the second blind via being positioned within the back isolation trench.

5. The integrated passive device of claim 4, wherein the back isolation trench includes a first stretch and a second stretch on opposite borders of the IPD respectively aligned with the first and second stretches of the front isolation trench, the second blind via being positioned within the first stretch of the back isolation trench and the through via being positioned within the second stretch of the back isolation trench.

6. The integrated passive device of claim 5, wherein the back isolation trench includes a third stretch and a fourth stretch on opposite borders of the IPD connecting the first and second stretches of the back isolation trench.

7. The integrated passive device of claim 1, wherein the plurality of layers further includes a front metallization layer arranged to promote electrical conductivity between the front conductive polymer layer and the second metal contact and a back metallization layer arranged to promote electrical conductivity between the back conductive polymer layer and the second metal contact.

8. The integrated passive device of claim 7, wherein the plurality of layers further incudes a front carbonaceous layer on the front conductive polymer layer and a back carbonaceous layer on the back conductive polymer layer, the front metallization layer being on the front carbonaceous layer and the back metallization layer being on the back carbonaceous layer.

9. An integrated passive device (IPD) comprising:
a conductive substrate having a front side and a back side;
a plurality of layers including a front dielectric layer on the front side of the conductive substrate, a back dielectric layer on the back side of the conductive substrate, a front conductive polymer layer on the front dielectric layer, and a back conductive polymer layer on the back dielectric layer, the plurality of layers defining a front isolation trench revealing the front side of the conductive substrate and a back isolation trench revealing the back side of the conductive substrate;
a first metal contact electrically connected to the conductive substrate; and
a second metal contact electrically isolated from the first metal contact and electrically connected to the front and back conductive polymer layers, the second metal contact being electrically connected to the back conductive polymer layer by way of a through via defined from the front outer surface of the IPD to a back outer surface of the IPD, the through via being positioned within the front isolation trench and the back isolation trench.

10. The integrated passive device of claim 9, wherein the front isolation trench includes a first stretch and a second stretch on opposite borders of the IPD and the back isolation trench includes a first stretch and a second stretch on opposite borders of the IPD respectively aligned with the first and second stretches of the front isolation trench, the through via being positioned within the second stretch of the front isolation trench and the second stretch of the back isolation trench.

11. The integrated passive device of claim 10, wherein the front isolation trench includes a third stretch and a fourth stretch on opposite borders of the IPD connecting the first and second stretches of the front isolation trench, and the back isolation trench includes a third stretch and a fourth stretch on opposite borders of the IPD connecting the first and second stretches of the back isolation trench.

12. The integrated passive device of claim 9, wherein the plurality of layers further includes a front metallization layer arranged to promote electrical conductivity between the front conductive polymer layer and the second metal contact and a back metallization layer arranged to promote electrical conductivity between the back conductive polymer layer and the second metal contact.

13. The integrated passive device of claim 12, wherein the plurality of layers further incudes a front carbonaceous layer on the front conductive polymer layer and a back carbonaceous layer on the back conductive polymer layer, the front metallization layer being on the front carbonaceous layer and the back metallization layer being on the back carbonaceous layer.

14. An integrated passive device (IPD) comprising:
a conductive substrate having a front side and a back side;
a plurality of layers including a front dielectric layer on the front side of the conductive substrate, a back dielectric layer on the back side of the conductive substrate, a front conductive polymer layer on the front dielectric layer, and a back conductive polymer layer on the back dielectric layer, the plurality of layers defining a front isolation trench revealing the front side of the conductive substrate and a back isolation trench revealing the back side of the conductive substrate;
a first metal contact electrically connected to the conductive substrate by way of a first blind via defined from a front outer surface of the IPD to the front side of the conductive substrate, the first blind via being positioned within the front isolation trench; and
a second metal contact electrically isolated from the first metal contact and electrically connected to the front and back conductive polymer layers.

15. The integrated passive device of claim 14, wherein the front isolation trench includes a first stretch and a second stretch on opposite borders of the IPD, the first blind via being positioned within the first stretch of the front isolation trench.

16. The integrated passive device of claim 14, further comprising a third metal contact electrically connected to the conductive substrate by way of a second blind via defined from a back outer surface of the IPD to the back side of the conductive substrate, the second blind via being positioned within the back isolation trench.

17. The integrated passive device of claim 16, wherein the back isolation trench includes a first stretch and a second stretch on opposite borders of the IPD respectively aligned with the first and second stretches of the front isolation trench, the second blind via being positioned within the first stretch of the back isolation trench.

18. The integrated passive device of claim 17, wherein the front isolation trench includes a third stretch and a fourth stretch on opposite borders of the IPD connecting the first and second stretches of the front isolation trench, and the back isolation trench includes a third stretch and a fourth stretch on opposite borders of the IPD connecting the first and second stretches of the back isolation trench.

19. The integrated passive device of claim 14, wherein the plurality of layers further includes a front metallization layer arranged to promote electrical conductivity between the front conductive polymer layer and the second metal contact and a back metallization layer arranged to promote electrical conductivity between the back conductive polymer layer and the second metal contact.

20. The integrated passive device of claim 19, wherein the plurality of layers further incudes a front carbonaceous layer on the front conductive polymer layer and a back carbonaceous layer on the back conductive polymer layer, the front metallization layer being on the front carbonaceous layer and the back metallization layer being on the back carbonaceous layer.
